(19) United States
(12) Patent Application Publication
(10) Pub. No.: US 2026/0148779 A1
(43) Pub. Date: May 28, 2026

(54) METHODS OF OPERATING MEMORY DEVICE, MEMORY DEVICES AND SYSTEMS

(71) Applicant: Yangtze Memory Technologies Holding Co., Ltd., Wuhan (CN)

(72) Inventors: Xinran Li, Wuhan (CN); Feng Xu, Wuhan (CN); Da Li, Wuhan (CN); Lei Jin, Wuhan (CN); Zongliang Huo, Wuhan (CN)

(73) Assignee: Yangtze Memory Technologies Holding Co., Ltd., Wuhan (CN)

(21) Appl. No.: 19/306,650

(22) Filed: Aug. 21, 2025

(30) Foreign Application Priority Data
Nov. 27, 2024 (CN) 202411722289.8

(51) Int. Cl. G11C 16/34; G11C 16/10; G11C 16/30

(52) U.S. Cl. CPC G11C 16/3459; G11C 16/102; G11C 16/30

(57) ABSTRACT

An example method of operating a memory device includes performing a program operation on a first memory cell in a first program operation phase and performing a program operation on a second memory cell and applying a program-inhibiting voltage to a first bit line coupled to the first memory cell in a second program operation phase. The first memory cell and the second memory cell are coupled to a same word line. A target threshold voltage of the first memory cell is greater than a target threshold voltage of the second memory cell. The first program operation phase precedes the second program operation phase.

### CROSS-REFERENCE TO RELATED APPLICATIONS

The present application claims the benefit of priority to China Application No. 202411722289.8, filed on Nov. 27, 2024, the content of which is incorporated herein by reference in its entirety.

### TECHNICAL FIELD

This disclosure relates to the technical field of semiconductor chips, and in some examples to methods of operating memory device, memory devices and systems.

### BACKGROUND

Flash memory device is a memory device with characteristics such as data non-volatility, fast read/write speed, low power consumption, long service life and the like. A memory-based computing in memory (CIM) technology uses Kirchhoff's law and Ohm's law to implement multiply-add operations of weight data and input data by writing (also referred to as programming) weight data into memory cells in a memory device, and is widely used in an artificial intelligence (AI) scenario. The precision of writing the weight data into the memory cell affects the accuracy of the computing in memory device.

### SUMMARY

In a first aspect, this disclosure provides a method of operating a memory device. The method includes: performing a program operation on a first memory cell in a first program operation phase; performing a program operation on a second memory cell and applying a program-inhibiting voltage to a first bit line coupled to the first memory cell in a second program operation phase; wherein the first memory cell and the second memory cell are coupled to a same word line of the word lines, a target threshold voltage of the first memory cell is greater than a target threshold voltage of the second memory cell, and the first program operation phase precedes the second program operation phase.

In some possible implementations, the method further includes: applying a program-inhibiting voltage to a second bit line coupled to the second memory cell in the first program operation phase.

In some possible implementations, the method further includes: in a verify phase in the first program operation phase, applying a first verify voltage to the word line coupled to the first memory cell and the second memory cell to verify the threshold voltage of the first memory cell; in a verify phase in the second program operation phase, applying a second verify voltage to the word line coupled to the first memory cell and the second memory cell to verify a threshold voltage of the second memory cell, wherein the first verify voltage is greater than the second verify voltage.

In some possible implementations, the method further includes: performing a program operation on the second memory cell in the first program operation phase.

In some possible implementations, the method further includes: in a verify phase in the first program operation phase, in a first phase, applying a first verify voltage to the word line coupled to the first memory cell and the second memory cell to verify the threshold voltage of the first memory cell; in a second phase, applying a third verify voltage to the word line coupled to the first memory cell and the second memory cell to verify the threshold voltage of the second memory cell; and in a verify phase in the second program operation phase, applying a second verify voltage the word line coupled to the first memory cell and the second memory cell to verify the threshold voltage of the second memory cell; wherein the first verify voltage is greater than the second verify voltage, and the second verify voltage is greater than the third verify voltage.

In some possible implementations, the method further includes: before the second program operation phase, applying a second verify voltage to the word line coupled to the first memory cell and the second memory cell to verify the threshold voltage of the second memory cell; and in response to the threshold voltage of the second memory cell reaching the target threshold voltage of the second memory cell, applying a program-inhibiting voltage to the second bit line coupled to the second memory cell in a second program operation phase.

In some possible implementations, the method further includes: applying a first program voltage to the word line coupled to the first memory cell and the second memory cell in a programming phase in the first program operation phase; and applying a second program voltage to the word line coupled to the first memory cell and the second memory cell in a programming phase in the second program operation phase.

In some possible implementations, the first program voltage includes a plurality of pulse voltages of which voltages are sequentially incremented step by step, and the second program voltage includes a plurality of pulse voltages of which voltages are sequentially incremented step by step.

In some possible implementations, the initial voltage pulse of the first program voltage is not less than the initial voltage pulse of the second program voltage; or the incremented voltage per step for the first program voltage is not less than the incremented voltage per step for the second program voltage.

In some possible implementations, the first program voltage includes a plurality of pulse voltages of which voltages are sequentially incremented step by step, and the second program voltage includes a plurality of pulse voltages of a same voltage.

In some possible implementations, one or more pulse voltages in the first program voltage are greater than the pulse voltage in the second program voltage.

In some possible implementations, the first program voltage includes a plurality of pulse voltages of a same voltage, and the second program voltage includes a plurality of pulse voltages of a same voltage.

In some possible implementations, the pulse voltage in the first program voltage is greater than the pulse voltage in the second program voltage.

In some possible implementations, the first program voltage includes a plurality of pulse voltages of a same voltage, and the second program voltage includes a plurality of pulse voltages of which voltages are sequentially incremented step by step.

In some possible implementations, one or more pulse voltages in the second program voltage are less than the pulse voltages in the first program voltage.

In a second aspect, this disclosure provides a memory device. The memory device includes a memory array, a plurality of word lines, a plurality of bit lines, and a peripheral circuit. The memory array includes a plurality of memory cells including a first memory cell and a second memory cell. The plurality of word lines are coupled to the plurality of memory cells, and the first memory cell and the second memory cell are coupled to the same word line. The plurality of bit lines are coupled to the plurality of memory cells and include a first bit line and a second bit line, the first memory cell is coupled to the first bit line, and the second memory cell is coupled to the second bit line. The peripheral circuit is coupled with the plurality of word lines and the plurality of bit lines. The peripheral circuit is configured to: perform a program operation on the first memory cell in a first program operation phase; perform a program operation on the second memory cell and apply a program-inhibiting voltage to the first bit line in a second program operation phase; wherein the target threshold voltage of the first memory cell is greater than the target threshold voltage of the second memory cell; and the first program operation phase precedes the second program operation phase.

In some possible implementations, the peripheral circuit is further configured to apply a program-inhibiting voltage to the second bit line in the first program operation phase.

In some possible implementations, the peripheral circuit is further configured to: in a verify phase in the first program operation phase, verify the threshold voltage of the first memory cell by applying a first verify voltage to the word line coupled to the first memory cell and the second memory cell; in a verify phase in the second program operation phase, verify the threshold voltage of the second memory cell by applying a second verify voltage to the word line coupled to the first memory cell and the second memory cell; wherein the first verify voltage is greater than the second verify voltage.

In some possible implementations, the peripheral circuit is further configured to perform a program operation on the second memory cell in the first program operation phase.

In some possible implementations, the peripheral circuit is further configured to: in a verify phase in the first program operation phase, in a first phase, verify the threshold voltage of the first memory cell by applying a first verify voltage to the word line coupled to the first memory cell and the second memory cell; in a second phase, verify the threshold voltage of the second memory cell by applying a third verify voltage to the word line coupled to the first memory cell and the second memory cell; and in a verify phase in the second program operation phase, verify the threshold voltage of the second memory cell by applying a second verify voltage to the word line coupled to the first memory cell and the second memory cell; wherein the first verify voltage is greater than the second verify voltage, and the second verify voltage is greater than the third verify voltage.

In some possible implementations, the peripheral circuit is further configured to verify the threshold voltage of the second memory cell by applying a second verify voltage to the word line coupled to the first memory cell and the second memory cell before the second program operation phase; and in response to the threshold voltage of the second memory cell reaching the target threshold voltage of the second memory cell, apply a program-inhibiting voltage to the second bit line in the second program operation phase.

In some possible implementations, the peripheral circuit is further configured to: apply a first program voltage to the word line coupled to the first memory cell and the second memory cell in a programming phase in the first program operation phase; and apply a second program voltage to the word line coupled to the first memory cell and the second memory cell in a programming phase in the second program operation phase.

In some possible implementations, the first program voltage includes a plurality of pulse voltages of which voltages are sequentially incremented step by step, and the second program voltage includes a plurality of pulse voltages of which voltages are sequentially incremented step by step.

In some possible implementations, the initial voltage pulse of the first program voltage is not less than the initial voltage pulse of the second program voltage; or the incremented voltage per step for the first program voltage is not less than the incremented voltage per step for the second program voltage.

In some possible implementations, the first program voltage includes a plurality of pulse voltages of which voltages are sequentially incremented step by step, and the second program voltage includes a plurality of pulse voltages of a same voltage.

In some possible implementations, one or more pulse voltages in the first program voltage are greater than the pulse voltage in the second program voltage.

In some possible implementations, the first program voltage includes a plurality of pulse voltages of a same voltage, and the second program voltage includes a plurality of pulse voltages of a same voltage.

In some possible implementations, the pulse voltage in the first program voltage is greater than the pulse voltage in the second program voltage.

In some possible implementations, the first program voltage includes a plurality of pulse voltages of a same voltage, and the second program voltage includes a plurality of pulse voltages of which voltages are sequentially incremented step by step.

In some possible implementations, one or more pulse voltages in the second program voltage are less than the pulse voltages in the first program voltage.

In a third aspect, this disclosure provides a system. The system includes a processor and the memory device according to any implementation of the second aspect, wherein the processor is coupled to the memory device, and the processor is configured to control the memory device.

### BRIEF DESCRIPTION OF THE DRAWINGS

In order to describe the technical solutions in this disclosure more clearly, the accompanying drawings that need to be used in some examples of this disclosure will be briefly described below, and obviously, the accompanying drawings described below are merely the accompanying drawings of some examples of this disclosure, and for the skilled in the art, other accompanying drawings may be obtained based on these accompanying drawings. In addition, the accompanying drawings in the following description may be considered as schematic diagrams, and do not limit actual sizes of products, actual procedures of methods, actual timing of signals, and the like in the examples of this disclosure.

FIG. 1 is a schematic structural diagram of a memory device provided by an example of this disclosure.

FIG. 2 is a schematic structural diagram of a memory block provided by an example of this disclosure.

FIG. 3 is a schematic diagram of partial cross-section of a memory string provided by an example of this disclosure.

FIG. 4 is a schematic diagram of a connection structure between a peripheral circuit and a memory array provided by an example of this disclosure.

FIG. 5 is a schematic diagram of threshold voltage distribution of a memory cell in a single-level cell storage mode provided by an example of this disclosure.

FIG. 6 is a schematic diagram of the calculation principle of memory-based computing in memory device provided by an example of this disclosure.

FIG. 7 is a schematic diagram of variation of threshold voltage distribution intervals in an ISPP programming manner provided by an example of this disclosure.

FIG. 8 is a schematic flowchart of a method of operating a memory device provided by an example of this disclosure.

FIG. 9 is a schematic diagram of a first voltage waveform applied by a peripheral circuit to a word line and a bit line provided by an example of this disclosure.

FIG. 10 is a schematic diagram of variation of threshold voltage distribution intervals in a programming manner using the voltage waveform shown in FIG. 9 provided by an example of this disclosure.

FIG. 11 is a schematic diagram of a second voltage waveform applied by the peripheral circuit to a word line and a bit line provided by an example of this disclosure.

FIG. 12 is a schematic diagram of variation of threshold voltage distribution intervals in a programming manner using the voltage waveform shown in FIG. 11 provided by an example of this disclosure.

FIG. 13 is a schematic diagram of a first voltage waveform for a first program voltage and a second program voltage provided by an example of this disclosure.

FIG. 14 is a schematic diagram of a second voltage waveform for the first program voltage and the second program voltage provided by an example of this disclosure.

FIG. 15 is a schematic diagram of a third voltage waveform for the first program voltage and the second program voltage provided by an example of this disclosure.

FIG. 16 is a schematic diagram of a fourth voltage waveform for the first program voltage and the second program voltage provided by an example of this disclosure.

FIG. 17 is a schematic diagram of a voltage waveform applied by the peripheral circuit to a word line and a bit line when the threshold voltage of the second memory cell is being verified at a time between the first program operation phase and the second program operation phase provided by an example of this disclosure.

FIG. 18 is a schematic structural diagram of a system provided by an example of this disclosure.

FIG. 19 is a schematic structural diagram of another system provided by an example of this disclosure.

### DETAILED DESCRIPTION

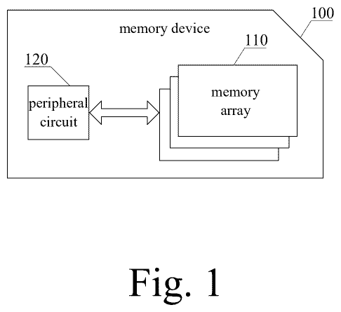

The technical solutions in some examples of this disclosure will be clearly and completely described in conjunction with FIGS. 1 to 19 below. Obviously, the described examples are only a part of the examples of this disclosure, not all of them. All other examples obtained by the skilled in the art based on the examples provided in this disclosure are within the protection scope of this disclosure.

Unless otherwise required by the context, throughout the specification and claims, the term “including” is interpreted as open and inclusive, that is, meaning “including, but not limited to”. In the description of the specification, the terms “one example”, “some examples”, “exemplarily” or “some examples” or the like are intended to indicate that specific features, structures, materials or characteristics related to the example or example are included in at least one example or example of the present application. The schematic representation of the above terms does not necessarily refer to the same example or example. In addition, specific features, structures, materials, or characteristics may be included in any appropriate manner in any one or more examples or examples.

Hereinafter, the terms “first” and “second” are used for descriptive purposes only, and cannot be construed as indicating or implying relative importance or implicitly indicating the number of technical features indicated. Thus, a feature defined with “first” and “second” may explicitly or implicitly include one or more of the features. In the description of the examples of this disclosure, unless otherwise specified, “a plurality of” means two or more.

In describing some examples, “coupled” and derivatives thereof may be used. For example, in describing some examples, the term “coupled” may be used to indicate that two or more components are in direct physical or electrical contact, in which case “coupled” may also be described as “connected”. Further, the term “coupled” may also mean that two or more components are not in direct contact with each other, but still cooperate or interact with each other. The examples disclosed herein are not necessarily limited herein.

The use of “configured to” herein means open and inclusive language that does not exclude devices that are applicable or configured to perform additional tasks or steps.

FIG. 1 shows a schematic structural diagram of a memory device provided by an example of this disclosure. As shown in FIG. 1, the memory device 100 may include a memory array 110 and a peripheral circuit 120, and the memory array 110 is coupled to the peripheral circuit 120. In some implementations, the peripheral circuit 120 and the memory array 110 may be separately formed on two wafers using different semiconductor manufacture processes. In some examples, the memory array 110 may be formed by using a mature manufacture process (for example, any manufacture process of 22 nm, 28 nm, and beyond) to ensure stability of stored data. The peripheral circuit 120 may be formed by using an advanced manufacture process (e. g., any manufacture process of 14 nm, 10 nm, and below), so as to help increase the data reading/storing speed of the memory device 100. Then, a wafer on which the memory array 110 is formed (which may be referred to as an array wafer) and a wafer on which the peripheral circuit 120 is formed (which may be referred to as a CMOS wafer) are bonded by a bonding process, so that the peripheral circuit 120 is coupled to the memory array 110.

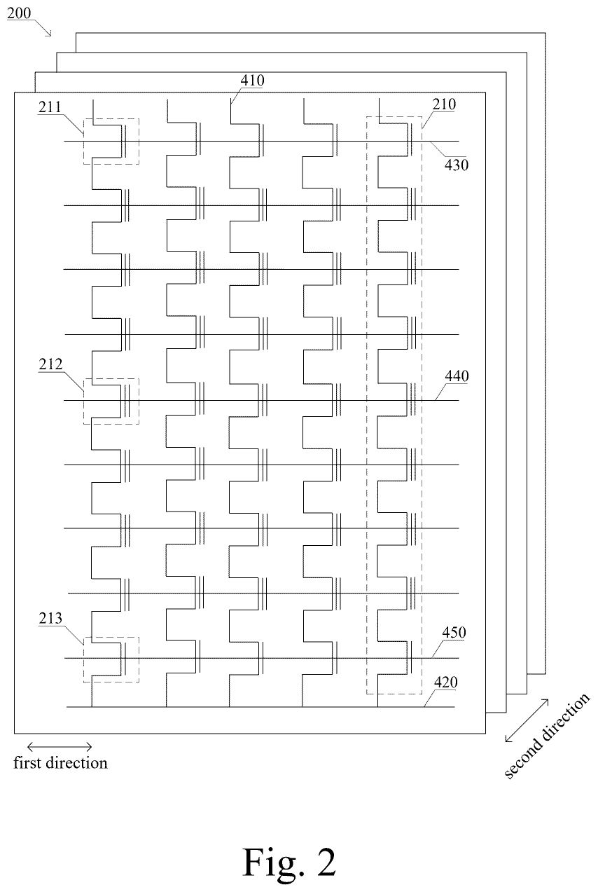

The memory array 110 may include a memory block 200. As shown in FIG. 2, in some implementations, the memory block 200 may include a plurality of memory strings 210, one end of the memory string 210 is coupled to a bit line (BL) 410, and the other end of the memory string 210 is coupled to a source line (SL) 420. Each memory string 210 may include a top select gate (TSG) 211, a plurality of memory cells 212, and a bottom select gate (BSG) 213 sequentially stacked in series. In some implementations, the memory cell 212 may be a device capable of storing charge such as a floating gate transistor or a charge trap type field effect transistor.

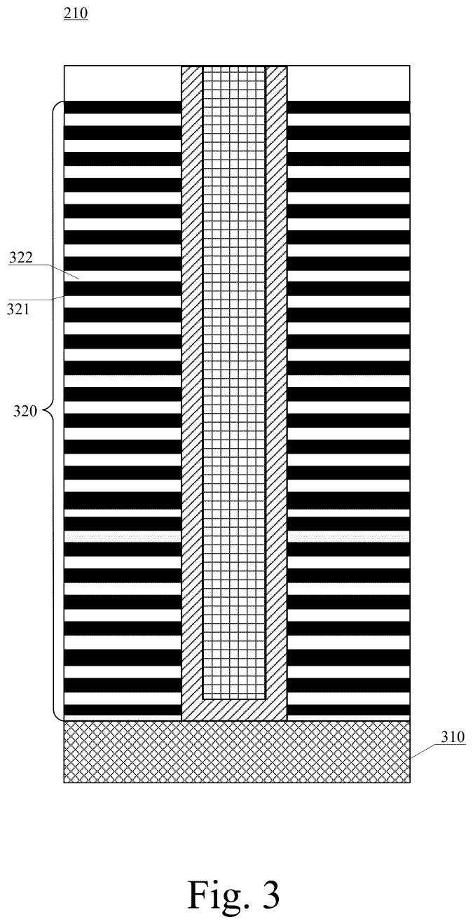

FIG. 3 shows a schematic diagram of partial cross-section of a possible memory string 210. The memory string 210 may extend vertically over the semiconductor layer 310. The semiconductor layer 310 may include silicon (e. g., monocrystalline silicon), silicon germanium (SiGe), gallium arsenide (GaAs), germanium (Ge), silicon-on-insulator (SOI), germanium-on-insulator (GOI), or any other suitable material.

The memory string 210 may include a channel structure penetrating through the stack structure 320 which may include alternating gate conductive layers 321 and dielectric layers 322. The number of gate conductive layers 321 and dielectric layers 322 in the stack structure 320 is related to the number of memory cells 212 in the memory string 210.

The gate conductive layers 321 may include a conductive material including, but not limited to, tungsten (W), cobalt (Co), copper (Cu), aluminum (Al), polysilicon, doped silicon, silicide, or any combination thereof. In some implementations, each gate conductive layer 321 includes a metal layer, e. g., a tungsten layer. In some implementations, each gate conductive layer 321 includes a doped polysilicon layer. Each gate conductive layer 321 may include a control gate surrounding the memory cell 212, and the gate conductive layer 321 at the top of the stack structure 320 may extend laterally and couple with a top select line (TSL) 430, the gate conductive layer 321 at the bottom of the stack structure 320 may extend laterally and couple with a bottom select line (BSL) 450, or the gate conductive layer 321 between the top select line 430 and the bottom select line 450 may extend laterally and couple with a word line (WL) 440.

It should be understood that although not shown in FIG. 3, additional components of the memory string 210 may be formed including, but not limited to, gate line slits/source contacts, local contacts, interconnect layers, etc.

Still referring to FIG. 2, the memory strings 210 may be arranged along a first direction to form a row, and a plurality of rows of the memory strings 210 may be arranged along a second direction perpendicular to the first direction to form a memory block 200. In some examples, among the memory strings 210 in the same row, the gate of the top selection transistor 211 of each memory string 210 may be coupled to the same top selection line 430; in some examples, the gates of the top selection transistors 211 of some rows of memory strings 210 in the plurality of rows of memory strings 210 may be coupled to the same top selection line 430; and the memory strings 210 whose gates of the top selection transistors 211 are coupled to the same top selection line 430 can form a memory plane. The gate of the bottom select transistor 213 in each memory string 210 may be coupled to the same bottom select line 450. In some implementations, the selected memory string 210 can be activated during read, program, and erase operations by the top select line 430 and the bottom select line 450.

Each memory string 210 is coupled to the peripheral circuit 120 through a corresponding bit line 410, e. g., the drain of top select transistor 211 in memory string 210 is coupled to a bit line 410. In order to reduce the number of the bit lines 410, the memory strings 210 in any one of the memory planes may be coupled to the same bit line 410 as the memory string 210 in corresponding position in other memory plane.

For a plurality of memory strings 210 in the memory block 200, the control gate of a memory cell 212 in any one of the memory strings 210 and the control gate of the memory cell 212 at corresponding position in other memory string 210 may be coupled to the same word line 440. The source of the bottom select transistor 213 in the memory string 210 may be coupled to the source line 420 (or a common source line (CSL)).

It should be noted that the drawings of the present disclosure only illustrate the structure of the memory block 200 in some examples, but in practice, the structure of the memory block 200 may also be in other manners.

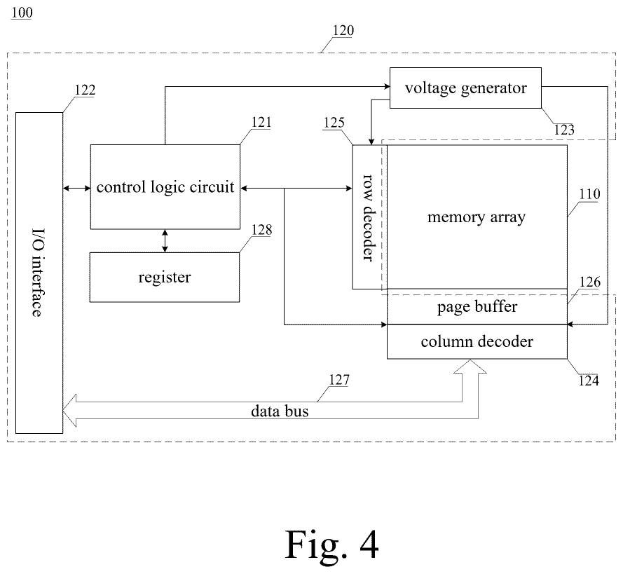

As shown in FIG. 4, in some implementations, the peripheral circuit 120 includes a control logic circuit 121, an I/O interface 122, a voltage generator 123, a column decoder 124, a row decoder 125, a page buffer 126, a data bus 127, and a register 128. It should be understood that, in some examples, additional circuits not shown in FIG. 4 may also be included.

The control logic circuit 121 may be coupled to the voltage generator 123, the page buffer 126, the column decoder 124, the row decoder 125, and the I/O interface 122, etc., and configured to control operations of the various peripheral circuit 120. The control logic circuit 121 may generate an operation signal to control operations of the row decoder 125, the column decoder 124, the page buffer 126, and the voltage generator 123 in response to a command (CMD) or a control signal received by the I/O interface 122; wherein the command may be a program command, a read command, or the like.

The I/O interface 122 may be coupled to the control logic circuit 121 and act as a control buffer to buffer and relay control commands received from a host to the control logic circuit 121 and to buffer and relay status information received from the control logic circuit 121 to the host. The I/O interface 122 may also be coupled to the page buffer 126 through data bus 127 and act as a data interface and data buffer to buffer and relay data to the memory array 110, or buffer and relay data from the memory array 110 to the host.

The voltage generator 123 may use an external supply voltage or an internal supply voltage to generate various voltages for performing operations such as erase, program, read, and verify operation on the memory array 110; for example, a program voltage Vpgm, an erase voltage Vla, and a pass voltage Vpass applied to the word line 440, and the like, and combinations thereof.

The column decoder 124 may, in response to controls of the control logic circuit 121, select one or more memory strings 210 in memory array 110 by applying a bit line voltage generated from voltage generator 123.

The row decoder 125 may, in response to control of the control logic circuit 121, supply a word line voltage generated from the voltage generator 123 to a selected word line (selected WL) and unselected word lines (unselected WL) of the memory array 110. As described in detail below, the row decoder 125 is configured to perform a program operation on one or more memory cells 212 in the memory array 110 coupled to the selected word line.

The page buffer 126 is coupled to the memory array 110 through a bit line 410. In some examples, the page buffer 126 may read data from and program (write) data to the memory array 110 according to control signals from control logic circuit 121. In other examples, the page buffer 126 may store program data (write data) to be programmed into memory array 110. In further examples, the page buffer 126 may also perform a verify operation for programing to ensure that data has been correctly programmed into the memory cell 212 coupled to the selected word line.

Registers 128 may be coupled to a control logic circuit 121 and include a status register, a command register, and an address register for storing status information, command operation codes (OP codes), and command addresses for controlling the operation of each peripheral circuit 120.

The skilled in the art should understand that operation performed by the row decoder 125, the page buffer 126, the control logic circuit 121, and the voltage generator 123 described in this disclosure may be performed by a processing circuit. The processing circuit may include, but is not limited to, hardware of a logic circuit or a hardware/software combination of a processor executing software.

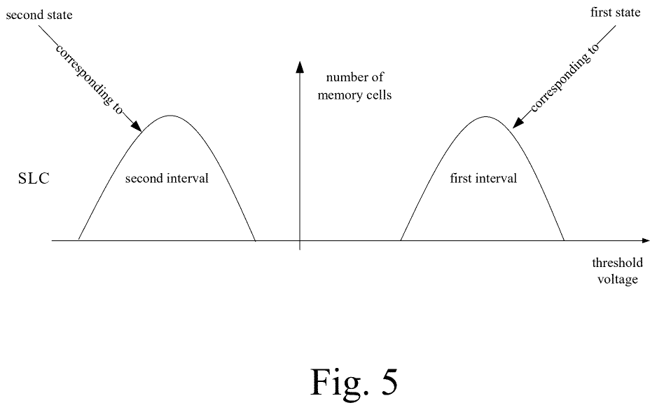

In some implementations, a computing function may be embedded in the memory device 100 to implement computing in memory device to reduce unnecessary data transmission. In some examples, artificial intelligence (AI) is an application (for example, a large model) that needs to perform matrix operations on a large amount of data, and computing in memory device can significantly reduce power consumption for data transmission and delay of data. In some implementations, the memory cell 212 implementing the computing in memory device may adopt a single-level cell (SLC) storage mode. As shown in FIG. 5, a memory cell 212 in a single-level cell mode may store one bit (that is, 1 bit), and may have a first state and a second state, and each state of the memory cell 212 has a one-to-one corresponding threshold voltage distribution interval, for example, the first state corresponds to a first interval and the second state corresponds to a second interval. In some examples, the first interval is located on the right side of the second interval, that is, the threshold voltage in the first interval is greater than the threshold voltage in the second interval, therefore in the first state and the second state, the first state may be referred to as a high state, and the second state may be referred to as a low state.

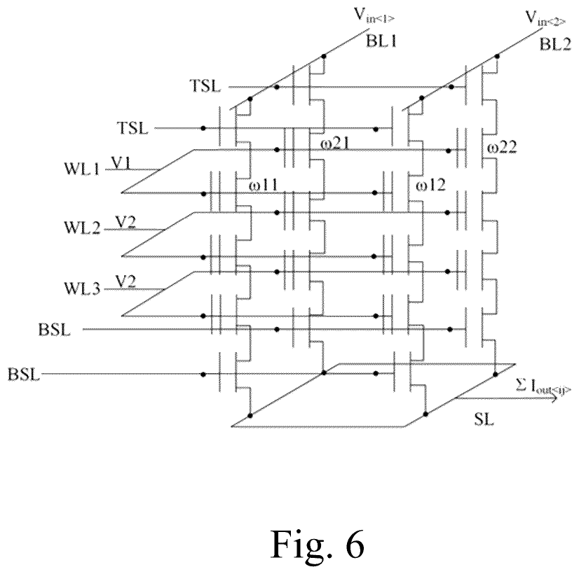

As shown in FIG. 6, in some examples, the memory device 100 based computing in memory device applies voltage values V_{in<i>} for indicating input data to a bit line 410 coupled to the memory array 110 (e. g., as shown in FIG. 6, apply V_{in<1>} to BL1 and apply V_{in<2>} to BL2), and applies a first voltage V1 to a selected word line (e. g., WL1 in FIG. 6) and a second voltage V2 to non-selected word lines (e. g., WL1 and WL2 in FIG. 6). In some examples, the first voltage V1 is located between the first interval and the second interval. Thus, in the memory cells 212 coupled to the selected word line, the first voltage V1 can turn on the memory cell 212 in the second state and cannot turn on the memory cell 212 in the first state. In some examples, the second voltage V2 is greater than any voltage in the first interval. Thus, the second voltage V2 can turn on any memory cell 212 coupled to the unselected word line.

Based on the above discussion, in each memory string 210, if the memory cell 212 coupled to the selected word line is in the second state, a current exists on the memory string 210; that is, the second state may represent that the weight data stored in the memory cell 212 is “1”. In some examples, the current on the memory string 210 may be expressed as follows:

$${I}_{o ut < ij >} = μ {C}_{o x} \frac{W}{L} ( {V}_{1} - {V}_{t h} ) ;$$

wherein μ is charge mobility, Cₒₓ is the gate oxide capacitance of the memory cell, W is the channel width of the memory cell, L is the channel length of the memory cell, and Vₜₕ is the threshold voltage of the memory cell. In each memory string 210, if the memory cell 212 coupled to the selected word line is in the first state, the current on the memory string 210 is small; that is, the first state may represent that the weight data stored in the memory cell 212 is “0”. The current on the respective memory strings 210 may finally converge on the source line 420 to achieve addition, thereby obtaining an output current for representing a multiply-add calculation result of the input data and the weight data (i.e., ΣI_{out<ij>} as shown in FIG. 6). It can be seen that the threshold voltage of the memory cell 212 in the second state has a large influence on the current on the memory string 210, and when the threshold voltage distribution interval (i.e., the second interval) corresponding to the second state is broadened, the weight data stored in some of the memory cells 212 in the second state is not accurate “1”, thereby affecting the accuracy of the computing in memory device to some extent.

In some implementations, the peripheral circuit 120 may perform a program operation on the memory cell 212 by means of increment step pulse program (ISPP), so that the threshold voltage of the memory cell 212 reaches a desired threshold voltage distribution interval. In some examples, a program operation may include multiple program cycles, each program cycle may include a programming phase and a verify phase. In the programming phase, the peripheral circuit 120 applies a program voltage Vpgm to the selected word line, so that charges enter into the floating gate layer (or charge trap) of the memory cell 212, and the threshold voltage of the memory cell 212 increases. In the verify phase, the peripheral circuit 120 verifies whether the threshold voltage of the memory cell 212 reaches the desired threshold voltage distribution interval by applying a verify voltage Vvfy to the selected word line. If the threshold voltage of the memory cell 212 reaches the desired threshold voltage distribution interval (i.e., the verifying passes), the memory cell 212 will be inhibited from programming in the next program cycle. In the programming phase in the next program cycle, the peripheral circuit 120 increases the program voltage Vpgm by an incremented voltage Vispp and apply it to the selected word line to at least program the memory cell 212 that fails to verify.

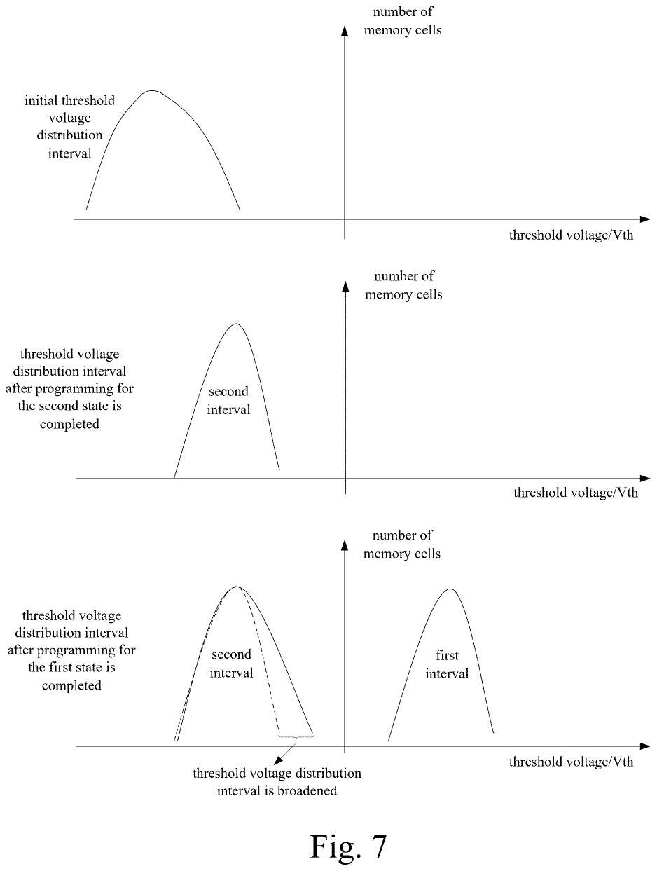

It can be seen that, the ISPP programming method causes, through multiple program cycles, the threshold voltage of the memory cell 212 to gradually increase as the program cycle increases until the threshold voltage of the memory cell 212 reaches the desired threshold voltage distribution interval. Moreover, as shown in FIG. 7, since the first interval is located on the right side of the second interval, the threshold voltage of the memory cell 212 first reaches the second interval, and when the threshold voltage of the memory cell 212 that needs to be programmed to the second state (i.e., the low state) reaches the second interval, the memory cell 212 completes programming and is inhibited from programming in a subsequent program cycle. When the threshold voltage of the memory cell 212 that needs to be programmed to the first state (i.e., high state) reaches the second interval, the memory cell 212 has not completed programming and needs to be programmed continuously in a subsequent program cycle. That is, the memory cell 212 that needs to be programmed to the second state (i.e., low state) may complete programming first, and the memory cell 212 that needs to be programmed to the first state (i.e., high state) may complete programming later. Therefore, when the peripheral circuit 120 continues to program the memory cell 212 that needs to be programmed to the first state, although the memory cell 212 that needs to be programmed to the second state (i.e., the low state) is inhibited from being programmed by the peripheral circuit 120 as the programming has been completed for the memory cell 212, a program disturbance for continuing to program the memory cell 212 that needs to be programmed to the first state also affects the memory cell that has completed programming (i.e., the memory cell 212 that needs to be programmed to the second state), so that after the memory cell 212 that needs to be programmed to the first state (i.e., the high state) completes programming, there is a problem that the threshold voltage distribution interval (i.e., the second interval) corresponding to the second state is broadened, which affects accuracy of computing in memory device.

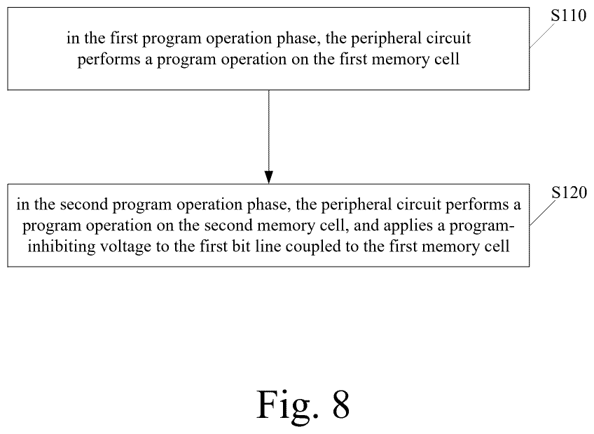

This disclosure provides a method of operating the memory device 100, as shown in FIG. 8, the method includes S110 to S120, where S110 precedes S120.

S110, in a first program operation phase, the peripheral circuit performs a program operation on the first memory cell.

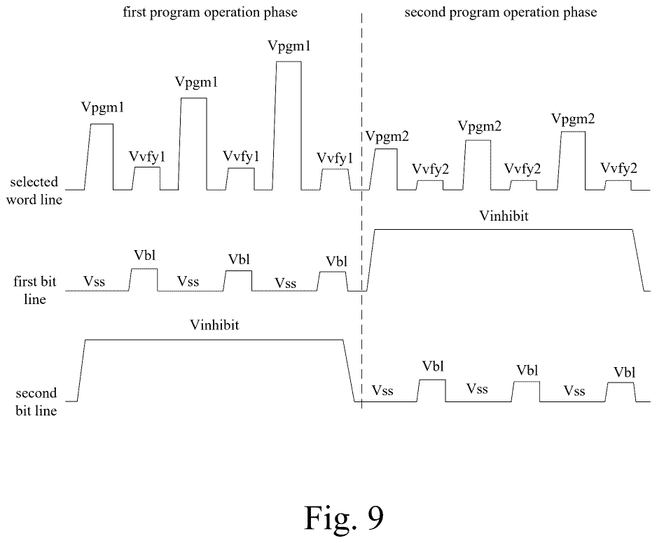

As shown in FIG. 9, in the programming phase in the first program operation phase, the peripheral circuit 120 applies the first program voltage Vpgm1 to the word line (i.e., the selected word line) coupled to the first memory cell, and applies the program select voltage Vss to the first bit line coupled to the first memory cell, thereby programming the first memory cell. In the verify phase in the first program operation phase, the peripheral circuit 120 applies the first verify voltage Vvfy1 to the selected word line and applies the bit line voltage Vbl to the first bit line to verify whether the threshold voltage of the first memory cell reaches the target threshold voltage of the first memory cell.

Still referring to FIG. 9, in some implementations, in the first program operation phase, the peripheral circuit 120 further applies a program-inhibiting voltage Vinhibit to the second bit line coupled to the second memory cell, thereby inhibiting programming the second memory cell. The first memory cell and the second memory cell are coupled to a same word line 440. The target threshold voltage of the first memory cell is any voltage in the first interval, the target threshold voltage of the second memory cell is any voltage in the second interval, and the target threshold voltage of the first memory cell is greater than the target threshold voltage of the second memory cell. That is, the first memory cell is the memory cell 212 that needs to be programmed to the first state, and the second memory cell is the memory cell 212 that needs to be programmed to the second state.

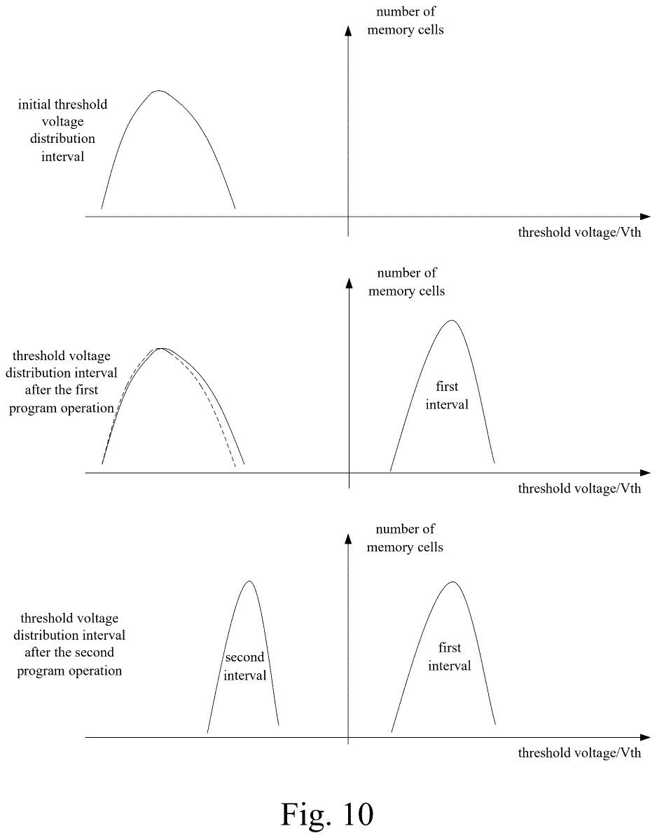

As shown in FIG. 10, in an implementation of this disclosure, the first memory cell is programmed in the first program operation phase, after the first program operation phase, the peripheral circuit 120 can program the threshold voltage of the first memory cell to the first interval, so that the first memory cell that needs to be programmed to the first state (that is, the high state) completes programming first. At the same time, in the first program operation phase, by applying the program-inhibiting voltage Vinhibit to the second bit line, the second memory cell is inhibited from being programmed, the second memory cell that needs to be programmed to the second state (i.e., the low state) has not completed programming, and the program disturb in the first program operation phase only causes the threshold voltage distribution interval of the second memory cell to be slightly broadened only on the basis of the initial threshold voltage distribution interval. That is, in the implementation of this disclosure, by changing the programming sequence, the first memory cell that needs to be programmed to the first state (that is, the high state) completes programming first, and the second memory cell that needs to be programmed to the second state (that is, the low state) completes programming later. Therefore, after the second memory cell that needs to be programmed to the second state (that is, the low state) is programmed, there is no problem that the program disturb may broaden the threshold voltage distribution interval (that is, the second interval) corresponding to the second state, thereby achieving the purpose of narrowing the second interval, and helping to improve the accuracy of computing in memory device.

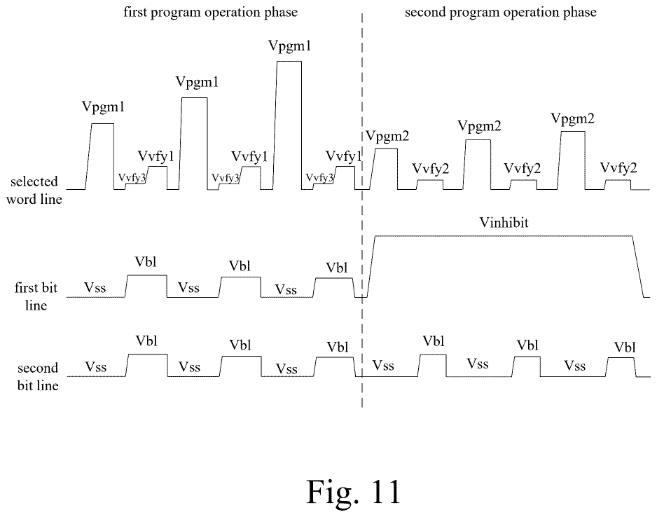

As shown in FIG. 11, in some other implementations, in the first program operation phase, the peripheral circuit 120 further performs a program operation on the second memory cell. Different from FIG. 9, in the programming phase in the first program operation phase, the peripheral circuit 120 applies the program select voltage Vss to both the first bit line and the second bit line. In the verify phase in the first program operation phase, the peripheral circuit 120 sequentially applies the third verify voltage Vvfy3 and the first verify voltage Vvfy1 to the word line 440 coupled to the first memory cell and the second memory cell, and applies the bit line voltage Vbl to the first bit line and the second bit line. The third verify voltage Vvfy3 is less than the first verify voltage Vvfy1, the first verify voltage Vvfy1 is to verify whether the threshold voltage of the first memory cell reaches the target threshold voltage of the first memory cell, and the third verify voltage Vvfy3 is to verify whether the threshold voltage of the second memory cell is close to the target threshold voltage of the second memory cell.

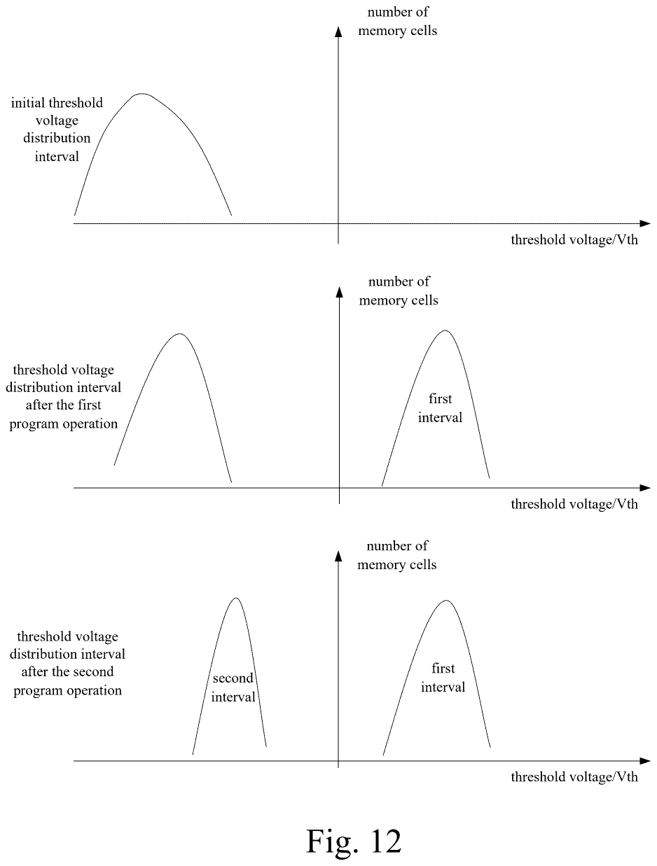

According to examples of this disclosure, the first memory cell and the second memory cell both are programmed in the first program operation stage. As shown in FIG. 12, after the first program operation phase, the peripheral circuit 120 programs the first memory cell to the first state (i.e., the high state), and the first memory cell completes programming. Since the third verify voltage Vvfy3 is small, the second memory cell can pass the verification more easily in the first program operation phase and is inhibited from programming. Only coarse programming is performed on the second memory cell in the first program operation phase, so that after the first program operation phase, the threshold voltage of the second memory cell may be close to the target threshold voltage of the second memory cell (the second memory cell has not completed programming), thereby helping to save the time required for performing fine programming on the second memory cell subsequently.

S120, in the second program operation phase, the peripheral circuit performs a program operation on the second memory cell, and applies a program-inhibiting voltage to the first bit line coupled to the first memory cell.

Still referring to FIG. 9, in the second program operation phase, the peripheral circuit 120 prohibits programming on the first memory cell by applying a program-inhibiting voltage Vinhibit to the first bit line. Moreover, in the programming phase in the second program operation phase, the peripheral circuit 120 applies the second program voltage Vpgm2 to the word line 440 (i.e., the selected word line) coupled to the second memory cell, and applies the program select voltage Vss to the second bit line, thereby programming the second memory cell. In the verify phase in the second program operation phase, the peripheral circuit 120 applies the second verify voltage Vvfy2 to the selected word line and applies the bit line voltage Vbl to the second bit line, to verify whether the threshold voltage of the second memory cell reaches the target threshold voltage of the second memory cell. As shown in FIG. 11, the second verify voltage Vvfy2 is greater than the third verify voltage Vvfy3, and the second verify voltage Vvfy2 is less than the first verify voltage Vvfy1.

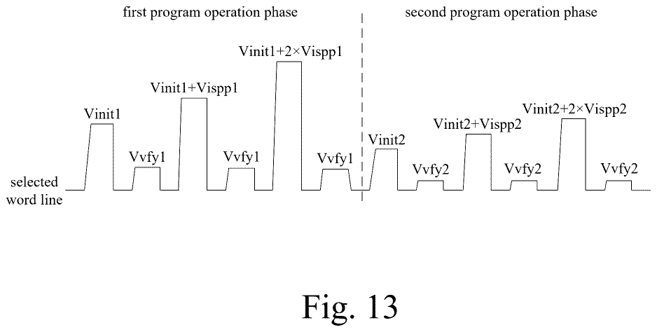

As shown in FIG. 13, in some implementations, the first program voltage Vpgm1 includes a plurality of pulse voltages of which voltages are sequentially incremented step by step, and the second program voltage Vpgm2 includes a plurality of pulse voltages of which voltages are sequentially incremented step by step. The initial pulse voltage Vinit1 of the first program voltage Vpgm1 and the initial pulse voltage Vinit2 of the second program voltage Vpgm2 may be the same or different. The incremented voltage Vispp1 for the first program voltage Vpgm1 and the incremented voltage Vispp2 for the second program voltage Vpgm2 may be the same or different. In some implementations, the initial pulse voltage Vinit1 of the first program voltage Vpgm1 is not less than the initial pulse voltage Vinit2 of the second program voltage Vpgm2. In some implementations, the incremented voltage Vispp1 per step for the first program voltage Vpgm1 is not less than the incremented voltage Vispp2 per step for the second program voltage Vpgm2.

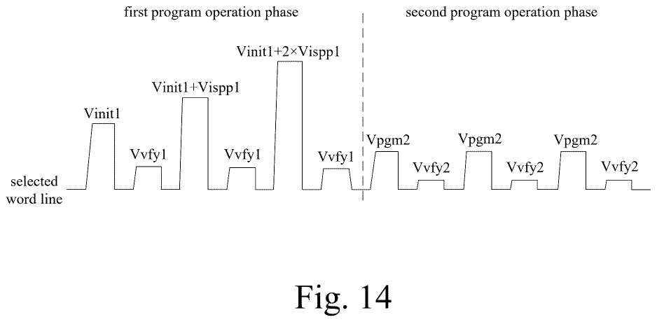

As shown in FIG. 14, In some implementations, the first program voltage Vpgm1 includes a plurality of pulse voltages of which voltages are sequentially incremented step by step, and the second program voltage Vpgm2 includes a plurality of pulse voltages of a same voltage. One or more pulse voltages in the first program voltage Vpgm1 are greater than the pulse voltage in the second program voltage Vpgm2.

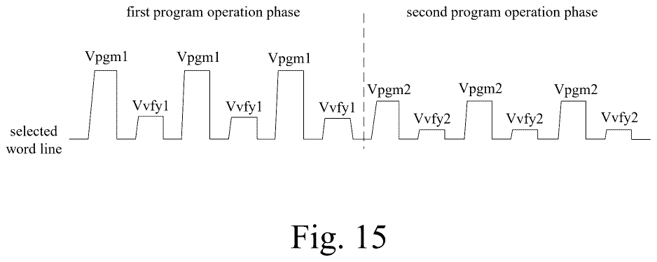

As shown in FIG. 15, in some implementations, the first program voltage Vpgm1 includes a plurality of pulse voltages of a same voltage, and the second program voltage Vpgm2 includes a plurality of pulse voltages of a same voltage. The pulse voltage in the first program voltage Vpgm1 is greater than the pulse voltage in the second program voltage Vpgm2.

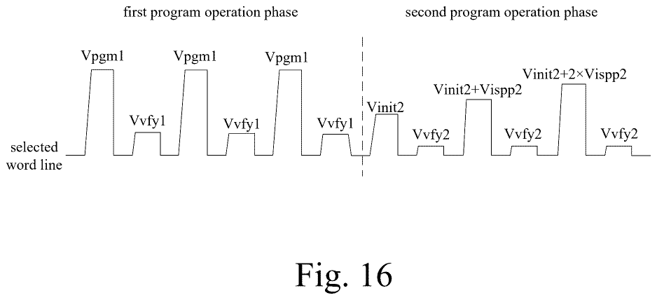

As shown in FIG. 16, in some implementations, the first program voltage Vpgm1 includes a plurality of pulse voltages of a same voltage, and the second program voltage Vpgm2 includes a plurality of pulse voltages of which voltages are sequentially incremented step by step. One or more pulse voltages in the second program voltage Vpgm2 are less than the pulse voltages in the first program voltage Vpgm1.

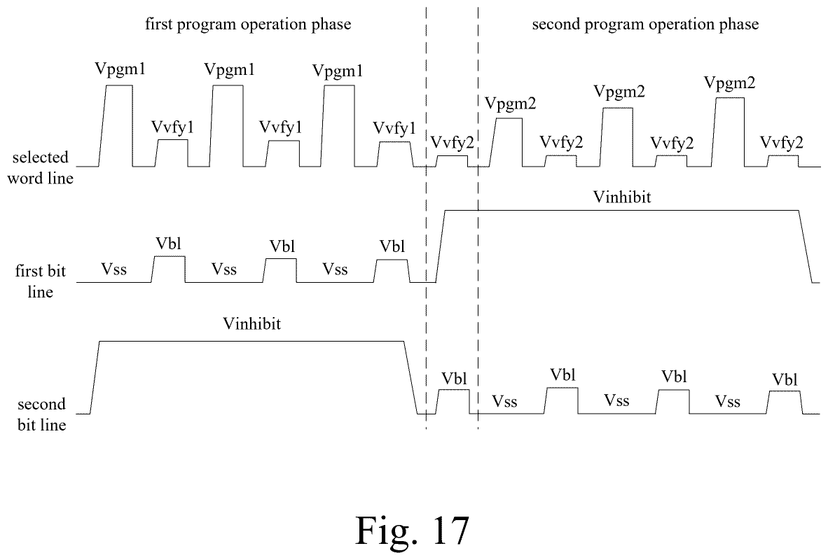

As shown in FIG. 17, in some implementations, after the first program operation phase and before the second program operation phase, the peripheral circuit 120 further applies a second verify voltage Vvfy2 to the word line 440 (i.e., the selected word line) coupled to the first memory cell and the second memory cell, and applies a bit line voltage Vbl to the second bit line, to verify the threshold voltage of the second memory cell. In response to the threshold voltage of the second memory cell reaching the target threshold voltage of the second memory cell (i.e., passing the verification), in the second program operation phase, the peripheral circuit 120 applies the program-inhibiting voltage Vinhibit to the second bit line, thereby inhibiting programming on the second memory cell passing the verification at the second program operation node, and avoiding over programming on the second memory cell.

Examples of this disclosure provide a system, and in some implementations, the system 500 may be applied to different types of electronic equipment, for example, any electronic equipment that can store data such as a mobile phone (for example, a handphone), a desktop computer, a tablet computer, a notebook computer, a server, an in-vehicle equipment, a game console, a printer, a positioning equipment, a wearable equipment, an intelligent sensor, a mobile power supply, a virtual reality (VR) equipment, an augmented reality (AR) equipment, and a server.

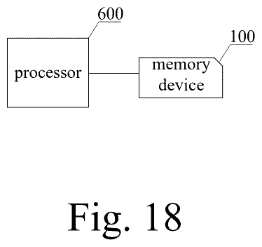

As shown in FIG. 18, the system 500 may include a processor 600 and a memory device 100 shown in FIG. 1. The processor 600 is coupled to the memory device 100, and the processor 600 may send commands to the memory device 100 to control operations (for example, a program operation, a read operation, and an erase operation) of the memory device 100. When the memory device 100 performs the program operation, the memory device 100 may perform the method shown in FIG. 8. In some implementations, the processor 600 may be a graphics processing unit (GPU), and the memory device 100 may be directly attached to or integrated on the GPU.

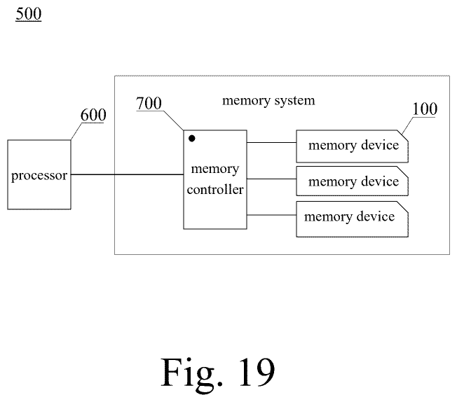

As shown in FIG. 19, in some implementations, the system 500 may further include a memory controller 700 coupled to one or more memories 100 to form a memory system. The memory controller 700 may be coupled to the processor 600 through at least one of various interface protocols, and the processor 600 controls operations (e. g., a program operation, a read operation and an erase operation, an arithmetic operation, etc.) of the memory device 100 through the memory controller 700. The interface protocol may include at least one of a universal serial bus (USB) protocol, a multimedia card (MMC) protocol, a peripheral component interconnect (PCI) protocol, a PCI-Express (PCI-E) protocol, an advanced technology attachment (ATA) protocol, a serial ATA protocol, a parallel ATA protocol, a small computer system interface (SCSI) protocol, an enhanced small disk interface (ESDI) protocol, or an integrated drive electronics (IDE) protocol.

It should be appreciated that the memory controller 700 may also be configured to manage various functions regarding data stored or to be stored in the memory device 100, including but not limited to bad block management, garbage collection, logical-to-physical address translation, wear leveling, and the like. Of course, the memory controller 700 may also perform any other suitable functions (e. g., formatting the memory device 100), which are not repeated herein.

Examples of this disclosure provide a method of operating a memory device, a memory device and a system. The method includes: performing a program operation on a first memory cell in a first program operation phase; performing a program operation on a second memory cell and applying a program-inhibiting voltage to a first bit line coupled to the first memory cell in a second program operation phase; wherein the first memory cell and the second memory cell are coupled to a same word line of the word lines, a target threshold voltage of the first memory cell is greater than a target threshold voltage of the second memory cell, and the first program operation phase precedes the second program operation phase. According to the example of this disclosure, the programming sequence is changed, so that the first memory cell that needs to be programmed to the first state (that is, the high state) completes programming first, and the second memory cell that needs to be programmed to the second state (that is, the low state) completes programming later. Therefore, after the second memory cell that needs to be programmed to the second state (that is, the low state) is programmed, there is no problem that the program disturb broadens the threshold voltage distribution interval (that is, the second interval) corresponding to the second state, thereby achieving the purpose of narrowing the second interval, and helping to improve the accuracy of computing in memory device.

Examples of this disclosure provide a computer-readable storage medium storing computer-executable instructions that can implement the method shown in FIG. 8 after being executed.

Examples of this disclosure provide a computer device including a processor and a readable storage medium coupled to the processor, wherein the readable storage medium stores executable instructions that can implement the method shown in FIG. 8 when executed by a processor.

The skilled in the art may clearly understand that, for ease and brevity of description, in the foregoing examples, the description of each example has its own emphasis, and for the parts that are not described in detail in a certain example, the corresponding process in the previous method example can be referred to, and will not be repeated here.

In several examples provided in this disclosure, it should be understood that the provided memory device, the method of operating a memory device, and the system may be implemented in another manner. For example, division of a module is merely a logical function division, and there may be another division manner in actual implementation, for example, a plurality of units or components may be combined or may be integrated into another system, or some features may be ignored or not performed.

The skilled in the art can appreciate that the modules and algorithm steps of the examples described in connection with the examples disclosed herein can be implemented in electronic hardware, or a combination of computer software and electronic hardware. Whether these functions are performed in hardware or software depends on the specific application and design constraints of the technical solution. The skilled in the art may use different methods to implement the described function for each particular application, but such implementation should not be considered beyond the scope of this disclosure.

The above is only detailed description of this disclosure, but the protection scope of this disclosure is not limited thereto, and any changes or substitutions that can be easily conceivable by the skilled in the art within the technical scope disclosed by this disclosure should be covered within the protection scope of this disclosure. Therefore, the protection scope of this disclosure shall be defined by the protection scope of the claims.

What is claimed is:

1. A method of operating a memory device, including:
performing a program operation on a first memory cell in a first program operation phase; and
performing a program operation on a second memory cell, and applying a program-inhibiting voltage to a first bit line coupled to the first memory cell in a second program operation phase,
wherein the first memory cell and the second memory cell are coupled to a same word line, a target threshold voltage of the first memory cell is greater than a target threshold voltage of the second memory cell, and the first program operation phase precedes the second program operation phase.

2. The method of claim 1, further including:
applying a program-inhibiting voltage to a second bit line coupled to the second memory cell in the first program operation phase.

3. The method of claim 2, further including:
applying a first verify voltage to the word line coupled to the first memory cell and the second memory cell, to verify a threshold voltage of the first memory cell in a verify phase in the first program operation phase; and
applying a second verify voltage to the word line coupled to the first memory cell and the second memory cell, to verify a threshold voltage of the second memory cell in a verify phase in the second program operation phase,
wherein the first verify voltage is greater than the second verify voltage.

4. The method of claim 1, further including:
performing a program operation on the second memory cell in the first program operation phase.

5. The method of claim 4, further including:
in a verify phase in the first program operation phase: in a first phase, applying a first verify voltage to the word line coupled to the first memory cell and the second memory cell, to verify a threshold voltage of the first memory cell; and in a second phase, applying a third verify voltage to the word line coupled to the first memory cell and the second memory cell, to verify a threshold voltage of the second memory cell; and
in a verify phase in the second program operation phase, applying a second verify voltage to the word line coupled to the first memory cell and the second memory cell, to verify a threshold voltage of the second memory cell,
wherein the first verify voltage is greater than the second verify voltage, and the second verify voltage is greater than the third verify voltage.

6. The method of claim 1, further including:
before the second program operation phase, applying a second verify voltage to the word line coupled to the first memory cell and the second memory cell, to verify a threshold voltage of the second memory cell; and
in response to the threshold voltage of the second memory cell reaching the target threshold voltage of the second memory cell, applying a program-inhibiting voltage to a second bit line coupled to the second memory cell in the second program operation phase.

7. The method of claim 1, further including:
applying a first program voltage to the word line coupled to the first memory cell and the second memory cell in a programming phase in the first program operation phase; and
applying a second program voltage to the word line coupled to the first memory cell and the second memory cell in a programming phase in the second program operation phase.

8. The method of claim 7, wherein the first program voltage includes a plurality of pulse voltages of which voltages are sequentially incremented step by step, and the second program voltage includes a plurality of pulse voltages of which voltages are sequentially incremented step by step.

9. The method of claim 8, wherein an initial voltage pulse of the first program voltage is not less than an initial voltage pulse of the second program voltage; or an incremented voltage per step for the first program voltage is not less than an incremented voltage per step for the second program voltage.

10. The method of claim 7, wherein the first program voltage includes a plurality of pulse voltages of which voltages are sequentially incremented step by step, and the second program voltage includes a plurality of pulse voltages of a same voltage.

11. The method of claim 10, wherein one or more pulse voltages in the first program voltage are greater than a pulse voltage in the second program voltage.

12. The method of claim 7, wherein the first program voltage includes a plurality of pulse voltages of a same voltage, and the second program voltage includes a plurality of pulse voltages of a same voltage.

13. The method of claim 12, wherein a pulse voltage in the first program voltage is greater than a pulse voltage in the second program voltage.

14. The method of claim 7, wherein the first program voltage includes a plurality of pulse voltages of a same voltage, and the second program voltage includes a plurality of pulse voltages of which voltages are sequentially incremented step by step.

15. The method of claim 14, wherein one or more pulse voltages in the second program voltage are less than a pulse voltage in the first program voltage.

16. A memory device, including:
a memory array including a plurality of memory cells, the plurality of memory cells including a first memory cell and a second memory cell;
a plurality of word lines coupled to the plurality of memory cells, wherein the first memory cell and the second memory cell are coupled to a same word line of the word lines;
a plurality of bit lines coupled to the plurality of memory cells and including a first bit line and a second bit line, wherein the first memory cell is coupled to the first bit line, and the second memory cell is coupled to the second bit line; and
a peripheral circuit coupled to the plurality of word lines and the plurality of bit lines, and configured to:
perform a program operation on the first memory cell in a first program operation phase; and
perform a program operation on the second memory cell, and apply a program-inhibiting voltage to the first bit line in a second program operation phase,
wherein a target threshold voltage of the first memory cell is greater than a target threshold voltage of the second memory cell, and the first program operation phase precedes the second program operation phase.

17. The memory device of claim 16, wherein the peripheral circuit is further configured to: apply a program-inhibiting voltage to the second bit line in the first program operation phase.

18. The memory device of claim 17, wherein the peripheral circuit is further configured to:
verify a threshold voltage of the first memory cell by applying a first verify voltage to the word line coupled to the first memory cell and the second memory cell in a verify phase in the first program operation phase; and
verify a threshold voltage of the second memory cell by applying a second verify voltage to the word line coupled to the first memory cell and the second memory cell in a verify phase in the second program operation phase,
wherein the first verify voltage is greater than the second verify voltage.

19. The memory device of claim 16, wherein the peripheral circuit is further configured to: perform a program operation on the second memory cell in the first program operation phase.

20. A system, including
a processor; and
a memory device couped to the processor, including:
a memory array including a plurality of memory cells, the plurality of memory cells including a first memory cell and a second memory cell;
a plurality of word lines coupled to the plurality of memory cells, wherein the first memory cell and the second memory cell are coupled to a same word line of the word lines;
a plurality of bit lines coupled to the plurality of memory cells and including a first bit line and a second bit line, wherein the first memory cell is coupled to the first bit line and the second memory cell is coupled to the second bit line; and
a peripheral circuit coupled to the plurality of word lines and the plurality of bit lines, and configured to:
perform a program operation on the first memory cell in a first program operation phase; and
perform a program operation on the second memory cell, and apply a program-inhibiting voltage to the first bit line in a second program operation phase,
wherein a target threshold voltage of the first memory cell is greater than a target threshold voltage of the second memory cell, and the first program operation phase precedes the second program operation phase.
